(19) United States
(12) Patent Application Publication
(10) Pub. No.: US 2025/0194377 A1
(43) Pub. Date: Jun. 12, 2025

(54) DISPLAY DEVICE

(71) Applicant: Japan Display Inc., Tokyo (JP)

(72) Inventors: Hayata AOKI, Tokyo (JP); Jun NITTA, Tokyo (JP); Marina MOCHIZUKI, Tokyo (JP)

(73) Assignee: Japan Display Inc., Tokyo (JP)

(21) Appl. No.: 18/969,274

(22) Filed: Dec. 5, 2024

(30) Foreign Application Priority Data
Dec. 12, 2023 (JP) 2023-209217

(51) Int. Cl. H10K 59/80; H10K 59/35

(52) U.S. Cl. CPC H10K 59/80518; H10K 59/35; H10K 59/80517

(57) ABSTRACT

According to one embodiment, in a display device, a first anode of a first pixel includes a first reflective electrode and a first transparent electrode, a second anode of a second pixel includes a second reflective electrode and a second transparent electrode, a third anode of a third pixel includes a third reflective electrode and a third transparent electrode, and a first thickness of the first transparent electrode, a second thickness of the second transparent electrode, and a third thickness of the third transparent electrode are less in this order.

### CROSS-REFERENCE TO RELATED APPLICATION

This application is based upon and claims the benefit of priority from Japanese Patent Application No. 2023-209217, filed Dec. 12, 2023, the entire contents of which are incorporated herein by reference.

### FIELD

Embodiments described herein relate generally to a display device.

### BACKGROUND

Organic electroluminescence (organic EL) display devices that emit light by using the energy released when holes injected from the anode recombine with electrons injected from the cathode have been developed.

### BRIEF DESCRIPTION OF THE DRAWINGS

FIG. 1 is a perspective view showing an entire display device according to Embodiment 1.

FIG. 2 is a partial plan view schematically showing a configuration example of the display device.

FIG. 3 is a cross-sectional view of the display device shown in FIG. 2, taken along line A1-A2.

FIG. 4 is a cross-sectional view schematically showing an example of Embodiment 1.

FIG. 5 is a cross-sectional view schematically showing an example of Embodiment 1.

FIG. 6 is a cross-sectional view illustrating a step in a method of manufacturing the display device of Embodiment 1.

FIG. 7 is a cross-sectional view illustrating another step in the method of manufacturing the display device of Embodiment 1.

FIG. 8 is a cross-sectional view illustrating still another step in the method of manufacturing the display device of Embodiment 1.

FIG. 9 is a cross-sectional view illustrating still another step in the method of manufacturing the display device of Embodiment 1.

FIG. 10 is a cross-sectional view illustrating still another step in the method of manufacturing the display device of Embodiment 1.

FIG. 11 is a cross-sectional view illustrating still another step in the method of manufacturing the display device of Embodiment 1.

FIG. 12 is a cross-sectional view illustrating still another step in the method of manufacturing the display device of Embodiment 1.

FIG. 13 is a cross-sectional view illustrating still another step in the method of manufacturing the display device of Embodiment 1.

FIG. 14 is a cross-sectional view illustrating still another step in the method of manufacturing the display device of Embodiment 1.

FIG. 15 is a cross-sectional view illustrating still another step in the method of manufacturing the display device of Embodiment 1.

FIG. 16 is a cross-sectional view illustrating still another step in the method of manufacturing the display device of Embodiment 1.

FIG. 17 is a cross-sectional view illustrating still another step in the method of manufacturing the display device of Embodiment 1.

FIG. 18 is a cross-sectional view illustrating still another step in the method of manufacturing the display device of Embodiment 1.

FIG. 19 is a cross-sectional view illustrating still another step in the method of manufacturing the display device of Embodiment 1.

FIG. 20 is a cross-sectional view illustrating still another step in the method of manufacturing the display device of Embodiment 1.

FIG. 21 is a cross-sectional view illustrating still another step in the method of manufacturing the display device of Embodiment 1.

FIG. 22 is a cross-sectional view illustrating a step in a method of manufacturing a display device of a comparative example.

FIG. 23 is a cross-sectional view illustrating another step in the method of manufacturing the display device of the comparative example.

FIG. 24 is a cross-sectional view illustrating another step in the method of manufacturing the display device of the comparative example.

FIG. 25 is a cross-sectional view showing a configuration example of a display device according to Embodiment 2.

### DETAILED DESCRIPTION

In general, according to one embodiment, a display device comprises
a plurality of pixels including first pixels that emit red light, second pixels that emit green light, and third pixels that emit blue light; and
a bank provided between each adjacent pair of the plurality of pixels, wherein
each of the plurality of pixels comprises, on a base,
an anode including a reflective electrode and a transparent electrode,
an organic EL layer provided on the anode,
a protective layer provided to cover a side surface of the organic EL layer, and
a cathode disposed in an aperture of the protective layer and the bank, so as to be in contact with the organic EL layer,
the first pixel comprises a first anode including a first reflective electrode and a first transparent electrode,
the second pixel comprises a second anode including a second reflective electrode and a second transparent electrode,
the third pixel comprises a third anode including a third reflective electrode and a third transparent electrode, and
a first thickness of the first transparent electrode, a second thickness of the second transparent electrode, and a third thickness of the third transparent electrode are less in this order.

An object of this embodiment is to provide a display device with an improved display quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction z is referred to as cross-sectional view.

### Embodiment 1

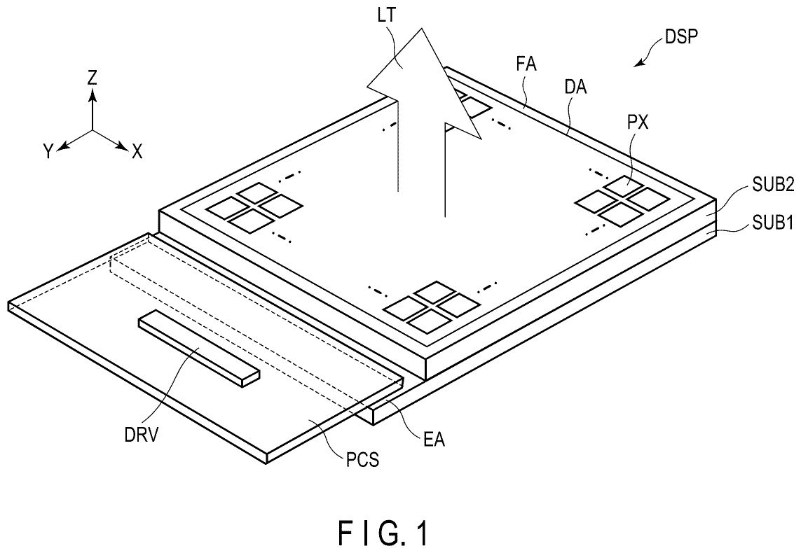

FIG. 1 is a perspective view showing a display device of Embodiment 1 in its entirety. A display device DSP has a display area DA and a peripheral area FA provided to surround the display area DA on a substrate SUB1. The display device DSP includes a plurality of pixels PX arranged in the display area DA. In the display device DSP, light LT is transmitted from a rear surface thereof to a front surface, and vice versa.

The display area DA has an upper surface on which a substrate SUB2 is provided with as a sealing material. The substrate SUB2 is fixed to the substrate SUB1 by sealant (not shown) provided to surround the display area DA. The display area DA formed on the substrate SUB1 is sealed by the substrate SUB2, as the sealing material, and the sealant so as not to be exposed to the atmosphere.

An area EA at an end portion of the substrate SUB1 is located on an outer side the substrate SUB2. In the area EA, a wiring substrate PCS is provided. The wiring substrate PCS is provided with a drive element DRV that outputs video signals and drive signals. The signals from the drive element DRV are input to the pixels PX in the display area DA via the wiring substrate PCS. The pixels PX emit light based on the video signals and various control signals.

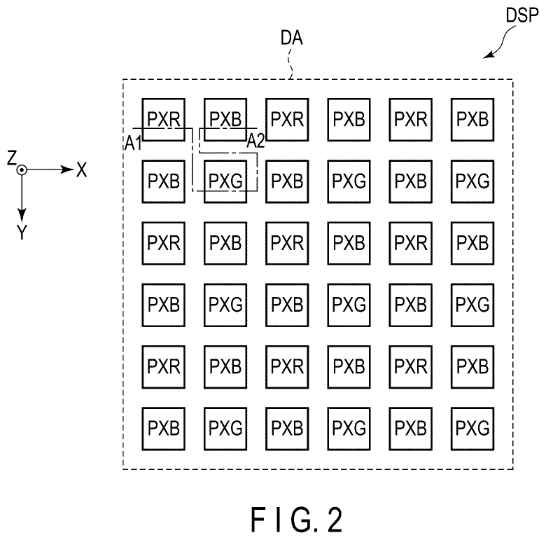

FIG. 2 is a partial plan view schematically showing a configuration example of a display device. The plurality of pixels PX include pixels PXR that emit red light, pixels PXG that emit green light, and pixels PXB that emit blue light. The pixels PXR, pixels PXG, and pixels PXB may as well be referred to as first pixels, second pixels, and third pixels, respectively. Each pixel PXR is arranged adjacent to respective pixels PXB along the first direction X and the second direction Y. Each pixel PXG is arranged adjacent to respective pixels PXB along the first direction X and the second direction Y. Each pixel PXB is arranged adjacent to a respective pixel PXR along the first direction and adjacent to a respective pixel PXG along the second direction Y.

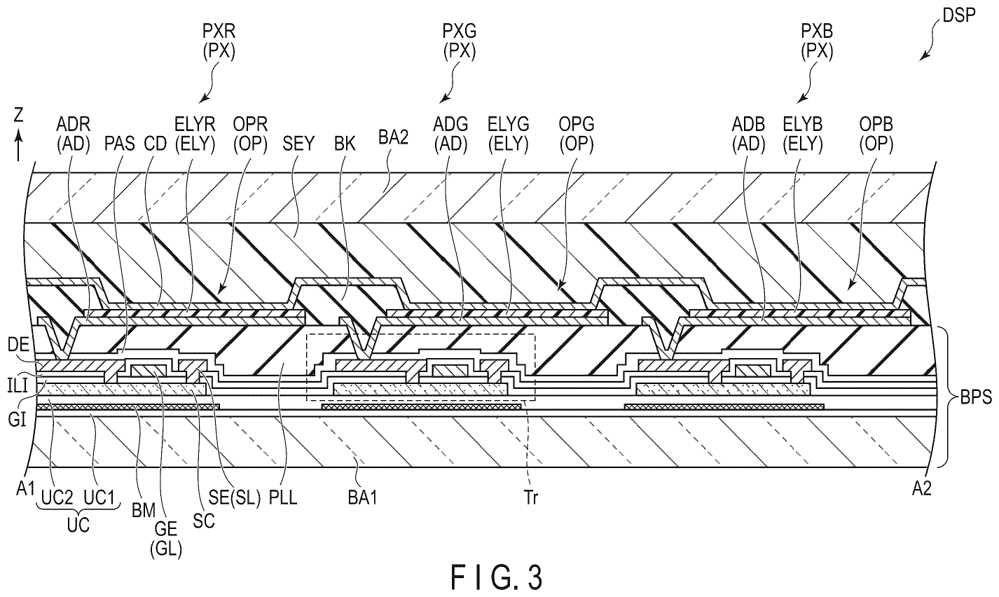

FIG. 3 is a cross-sectional view of the display device shown in FIG. 2 taken along line A1-A2.

A base BAL is made of a material, for example glass or a resin material. As the resin material, for example, acrylic, polyimide, polyethylene terephthalate, polyethylene naphthalate or the like may be used, and it may be formed in a single layer or multiple layers of any of these.

On the base BAL, an insulating layer UC1 is provided. The insulating layer UC1 is formed of a single layer of, for example, silicon oxide film or silicon nitride film or a stacked layer of these.

On the insulating layer UC1, a light shielding layer BM may be provided so as to overlap a transistor Tr. The light shielding layer BM suppresses changes in transistor characteristics due to the entering of light from a rear surface of a channel of the transistor Tr. When the light shielding layer BM is formed from a conductive layer, it is also possible to impart a back gate effect to the transistor Tr by applying a predetermined electric potential.

An insulating layer UC2 is provided to cover the insulating layer UC1 and the light shielding layer BM. For the material of the insulating layer UC2, a material similar to that of the insulating layer UC1 can be used. Note that the insulating layer UC2 may be made of a material different from that of the insulating layer UC1. For example, the insulating layer UC1 may be made of silicon oxide, and the insulating layer UC2 may be made of silicon nitride. The insulating layers UC1 and UC2 are collectively referred to as the insulating layer UC.

On the insulating layer UC, the transistor Tr is provided. The transistor Tr includes a semiconductor layer SC, an insulating layer GI, a gate electrode GE (scanning line), an insulating layer ILI, a source electrode SE (signal line), and a drain electrode DE.

For the semiconductor layer SC, amorphous silicon, polysilicon, or an oxide semiconductor is used.

As the insulating layer GI, a single layer of, for example, silicon oxide or silicon nitride or a stacked layer of these is provided.

For the gate electrode GE, for example, a molybdenum-tungsten alloy (MoW) is used. Note that the gate electrode GE may be formed to be integrated with the respective scanning line GL.

The insulating layer ILI is provided to cover the semiconductor layer SC and the gate electrode GE. The insulating layer ILI is formed from a single layer of, for example, silicon oxide or silicon nitride, or a stacked layer of these.

On the insulating layer ILI, a source electrode SE and a drain electrode DE are provided. The source electrode SE and the drain electrode DE are connected to the source region and the drain region of the semiconductor layer SC, respectively, via contact holes provided in the insulating layer ILI and the insulating layer GI, respectively. The source electrode SE may be formed to be integrated with the respective signal line.

An insulating layer PAS is provided to cover the source electrode SE, the drain electrode DE, and the insulating layer ILI. An insulating layer PLL is provided to cover the insulating layer PAS.

The insulating layer PAS is formed from an inorganic insulating material. The inorganic insulating material may be, for example, a single layer of silicon oxide or silicon nitride or a stacked layer of these. The insulating layer PLL is formed from an organic insulating material. The organic insulating material may be, for example, an organic material such as photosensitive acrylic, polyimide, or the like. With the insulating layer PLL thus provided, steps caused by the transistor Tr can be planarized.

On the insulating layer PLL, an anode AD is provided. The anode AD is connected to the drain electrode DE via respective contact holes provided in the insulating layers PAS and PLL. The anode provided in the pixel PXR is referred to as an anode ADR, the anode provided in the pixel PXB is referred to as an anode ADB, and the anode provided in the pixel PXG is referred to as an anode ADG. When there is no need to distinguish the anode ADR, anode ADG, and anode ADB from each other, they are simply referred to as an anode AD.

Details of the composition and materials of the anode AD will be described later.

In this embodiment, the configuration from the base BAL to the insulating layer PLL is referred to as a backplane BPS.

Between each adjacent pair of anodes AD, a bank (which may as well be referred to as a protrusion or a rib) is provided. For the material for the bank BK, an organic material similar to that of the insulating layer PLL is used. The bank BK is opened to expose a part of the anode AD.

An aperture in each pixel PXR is referred to as an aperture OPR, an aperture in each pixel PXB is referred to as an aperture OPB, and an aperture in each pixel PXG is referred to as an aperture OPG. When there is no need to distinguish the aperture OPR, aperture OPB, and aperture OPG, they are simply referred to as apertures OP.

An end portion of the aperture OP should preferably be formed into a smooth tapered shape in a cross-sectional view. If the end portion of the aperture OP is formed into a steep shape, a coverage error may occur in the organic EL layer ELY, which is formed later.

The organic EL layer ELY is provided between each adjacent pair of banks BK so as to overlap the respective anode AD. Although the details thereof will be described more later, the organic EL layer ELY includes an electron transport layer ETY, an emission layer EML, a hole transport layer HTL, and a hole injection layer HIL. The organic EL layer ELY may as well further include an electron injection layer, an electron blocking layer, and a hole blocking layer, if necessary.

The organic EL layer provided in the pixel PXR is referred to as an organic EL layer ELYR, the organic EL layer provided in the pixel PXB is referred to as an organic EL layer ELYB, and the organic EL layer provided in the pixel PXG is referred to as an organic EL layer ELYG. When there is no need to distinguish the organic EL layer ELYR, the organic EL layer ELYG, and the organic EL layer ELYB from each other, they are simply referred to as organic EL layers ELY.

On the organic EL layer ELY, a cathode CD is provided. The cathode CD is formed from, for example, a magnesium-silver alloy (MgAg) film, a single layer of silver (Ag) film, or a stacked layer of silver (Ag) and a transparent conductive material, or the like. For the transparent conductive material, for example, indium tin oxide (ITO), indium zinc oxide (IZO) or the like may be used.

An insulating layer SEY is provided to cover the cathode CD. The insulating layer SEY has a function of preventing moisture from penetrating into the organic EL layer ELY from outside. As the insulating layer SEY, a type having a high gas-barrier property is suitable. As the insulating layer SEY, for example, an insulating layer comprising an organic insulating layer interposed between two inorganic insulating layers containing nitrogen can be used. As the material for the organic insulating layer, acrylic resin, epoxy resin, polyimide resin or the like can be used. As the material for the inorganic insulating layer containing nitrogen, for example, silicon nitride or aluminum nitride can be used.

On the insulating layer SEY, a base BA2 is provided. The base BA2 is formed of a material similar to that of the base BAL. Between the base BA2 and the insulating layer SEY, an inorganic insulating layer or an organic insulating layer having light transmissivity may as well be provided. The organic insulating layer may as well have a function of adhering the insulating layer SEY and the base BA2 with each other.

The light emission generated by the organic EL layer ELY is extracted upwards via the cathode CD. In other words, the display device DSP of this embodiment has a top emission structure.

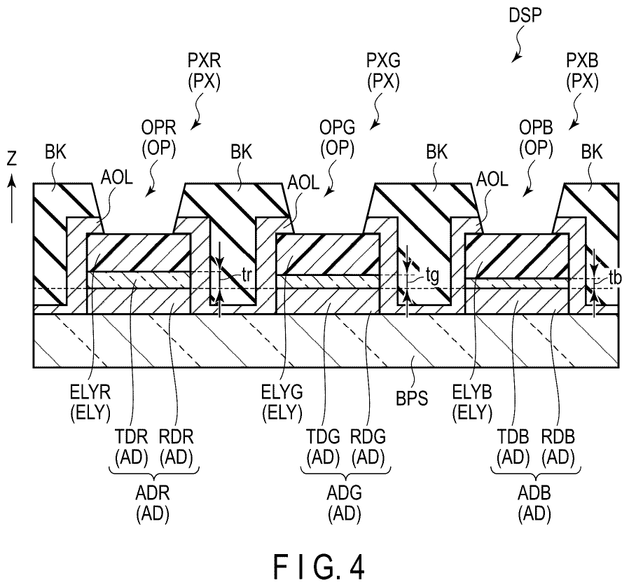

FIG. 4 is a cross-sectional diagram schematically showing an example of the configuration of Embodiment 1. Note that FIG. 4 only shows the configuration in the vicinity of the organic EL layer ELY in the display device DSP. In FIG. 4, the anodes AD (the anode ADR, anode ADG, anode ADB) are provided on the backplane BPS.

Each anode AD includes a reflective electrode RD and a transparent electrode TD. The reflective electrode RD and the transparent electrode TD are stacked one on the other in this order along the third direction Z.

The reflective electrode RD is formed using, for example, a conductive material having a high reflectivity, such as silver (Ag) or aluminum (Al). Apart from this, the reflective electrode RD may as well be formed using an aluminum (Al) alloy. In this case, the reflective electrode RD has a three-layer structure consisting in which a sufficiently thin layer of a barrier metal such as titanium (Ti) is stacked on aluminum (Al) or an aluminum alloy, and further a layer of indium tin oxide (ITO) is stacked on top. Examples of the material that can be alloyed with aluminum include neodymium (Nd), titanium (Ti), tantalum (Ta), and lanthanum (La). The transparent electrode TD is formed using, for example, indium zinc oxide (IZO) or indium zinc oxide (IZO).

The anode ADR includes a reflective electrode RDR and a transparent electrode TDR. The length (thickness) of the transparent electrode TDR taken along the third direction Z is defined as a thickness tr.

The anode ADG includes a reflective electrode RDG and a transparent electrode TDG. The length (thickness) of the transparent electrode TDG taken along the third direction Z is defined as a thickness tg.

The anode ADB includes a reflective electrode RDB and a transparent electrode TDB. The length (thickness) of the transparent electrode TDB taken along the third direction Z is defined as a thickness tb.

The thicknesses of the reflective electrode RDR, reflective electrode RDG, and reflective electrode RDB are the same as each other. On the other hand, the thickness is thinner in the transparent electrodes TDR, TDG, and TDB in this order (tr>tg>tb). The thicknesses of the reflective electrode RDR, reflective electrode RDG, and reflective electrode RDB are greater than the thickness tr of the transparent electrode TDR, the thickness tg of the transparent electrode TDG, and the thickness tb of the transparent electrode TDB, respectively.

The thickness tr of the transparent electrodes TDR, the thickness tg of the transparent electrodes TDG, and thickness tb of the transparent electrodes TDB are proportional to the wavelengths of the light emitted by these corresponding pixels, respectively. Of the pixels PXR, PXG, and PXB, the pixels PXR emitting red light exhibit light of the longest wavelength of these. Conversely, of the pixels PXR, PXG, and PXB, the pixels PXB emitting blue light exhibit light the shortest wavelength of these. Here, the wavelength of the light (red) emitted by pixels PXR is referred to as Δr, the wavelength of the light (green) emitted by the pixels PXG is referred to as Ag, and the wavelength of the light (blue) emitted by the pixels PXB is referred to as Ab. Then, the relationship of Δr>Δg>Δb is established. The thicknesses of the transparent electrode TDR, transparent electrode TDG, and transparent electrode TDB have a relationship in size (tr>tg>tb) the same as the relationship in degree for the wavelengths (Δr>λg>Δb) as mentioned above.

As described above, by adjusting the thickness of the transparent electrode TD, it is possible as well to adjust the length of the optical path from the reflective electrode RD to the emission layer EML.

The extraction efficiency of the blue light emitted from the organic EL layer ELYB is lower than that of the red or green light. Furthermore, when the thickness tb of the transparent electrode TDB is great, the blue light is absorbed. Thus, when the thickness tb of the transparent electrode TDB is great, the amount of blue light emitted from the pixel PXB becomes less than the amount of red or green light. Therefore, it is preferable that the thickness tb should be thinner. The thickness tb should preferably be about 20 nm. The difference between the thickness tg and the thickness tg should preferably be, for example, about 10 nm. Note that the difference between the thickness tg and the thickness as well should preferably be about 10 nm. That is, the thickness tb, thickness tg, and thickness tr should preferably be 20 nm, 30 nm, and 40 nm, respectively. In addition, when adjusting the length of the optical path, the thickness tb, thickness tg, and thickness tr may as well be 50 nm, 100 nm, and 150 nm, respectively.

If the thickness tr of the transparent electrode TDR is great, there are advantages in the manufacturing process, for example, in terms of the deposition tact time. Further, the extraction efficiency of the red light emitted from the organic EL layer ELYR is high. Therefore, even if the thickness tr of the transparent electrode TDR is great so that the light is absorbed by the transparent electrode TDR, the amount of red light emitted from the pixel PXR does not become lower as compared to that of the blue light.

On the anode ADR, an organic EL layer ELYR is provided. On the anode ADB, an organic EL layer ELYR is provided. On the anode ADG, an organic EL layer ELYR is provided. On the anode ADG, an organic EL layer ELYR is provided.

A protective layer AOL is provided to cover side surfaces of each of the anode ADR, the anode ADG, the anode ADB, the organic EL layer ELYR, the organic EL layer ELYG, and the organic EL layer ELYB. The protective layer AOL is formed, for example, of aluminum oxide (Alox).

On the protective layer AOL and between each adjacent pair of organic EL layers ELY, a bank BK is provided. The aperture OP (aperture OPR, OPB or OPG) is provided between each adjacent pair of banks BK. Although not shown in FIG. 4, the cathode CD is provided to cover the banks BK, the organic EL layers ELY, and the protective layers AOL.

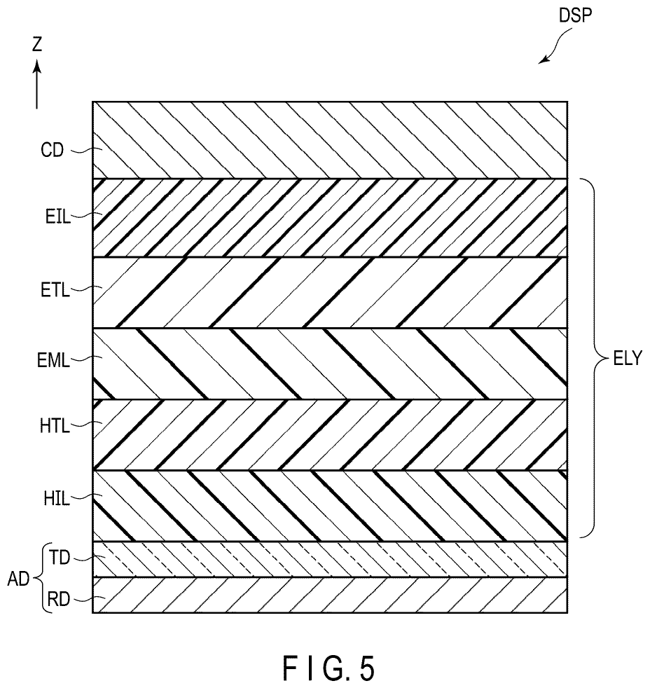

FIG. 5 is a cross-sectional view schematically showing an example of the configuration of Embodiment 1. FIG. 5 is a partial enlarged view of FIG. 4. As shown in FIG. 5, an organic EL layer ELY is provided between the anode AD and the cathode CD along the third direction Z. The organic EL layer ELY includes a hole injection layer HIL, a hole transport layer HTL, an emission layer EML, an electron transport layer ETL, and an electron injection layer EIL, which are stacked one on another along the third direction Z. The anode AD is a stacked body of a reflective electrode RD and a transparent electrode TD.

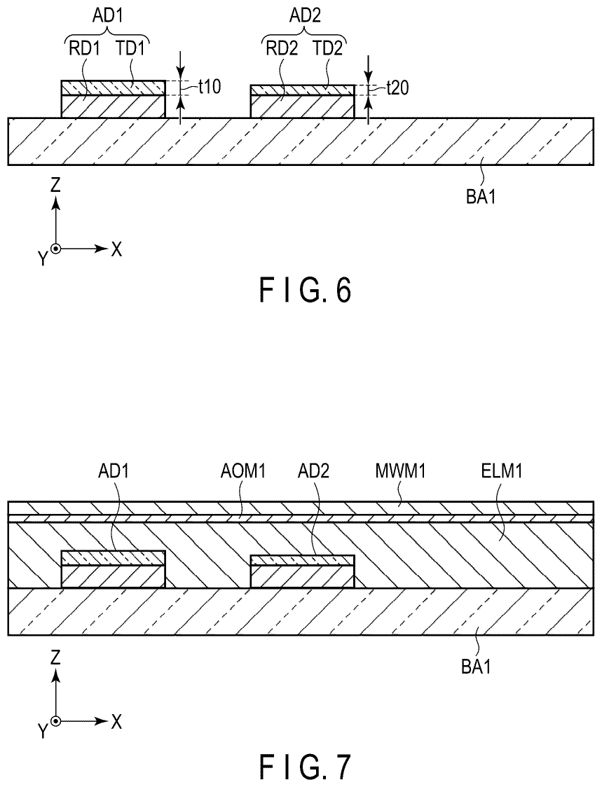

FIGS. 6 to 21 are each a cross-sectional view showing a respective step in a method of manufacturing the display device of Embodiment 1. In FIGS. 6 to 21, the first pixel, which is one of the pixel PXR, pixel PXG, and pixel PXB, is represented as a pixel PX1, and the second pixel, which is another one, is represented as a pixel PX2. In FIGS. 6 to 21, the first pixel (pixel PX1) and the second pixel (pixel PX2) are formed in this order. Although not shown in the figures, the third pixel (which is referred to as a pixel PX3), which is the other one of the pixel PXR, pixel PXG, and pixel PXB, is formed in a manner similar to those of the first and second pixels.

First, the anode AD1 and the anode AD2 are formed on the base BAL (see FIG. 6). The anode AD1 is the anode of the pixel PX1, and the anode AD2 is the anode of the pixel PX2. The anode AD1 includes a reflective electrode RD1 and a transparent electrode TD1. The anode AD2 includes a reflective electrode RD2 and a transparent electrode TD2.

Here, the thickness of the transparent electrode TD1 in FIG. 6 is defined as t10, and the thickness of the transparent electrode TD2 is defined as t20. The thickness t10 is greater than the thickness t20 (t10>t20).

An organic EL layer ELM1, a sacrificial layer AOM1, and a sacrificial layer MWM1 are formed to cover the base BA1, the anode AD1, and the anode AD2 (see FIG. 7). The organic EL layer ELM1 is an organic EL layer corresponding to the pixel PX1.

The sacrificial layer AOM1 is formed, for example, of aluminum oxide (AlOx). Aluminum oxide can be formed by atomic layer deposition (ALD).

The sacrificial layer MWM1 is formed, for example, of molybdenum tungsten (MoW). The molybdenum tungsten is formed by the sputtering method.

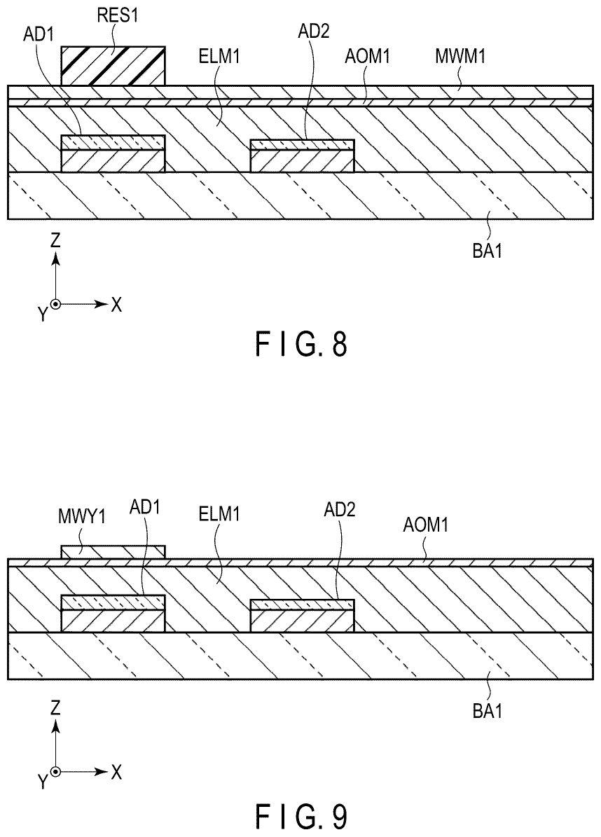

A resist mask RES1 is formed on the sacrificial layer MWM1 so as to oppose the anode AD1 (see FIG. 8). Note that no resist mask is formed on the anode AD2.

Using the resist mask RES1, the sacrificial layer MWM1 is partially removed by etching. With this processing, a sacrificial layer MWY1 is formed into an island-shape so as to oppose the anode AD1 and interpose the sacrificial layer AOM1 therebetween (see FIG. 9).

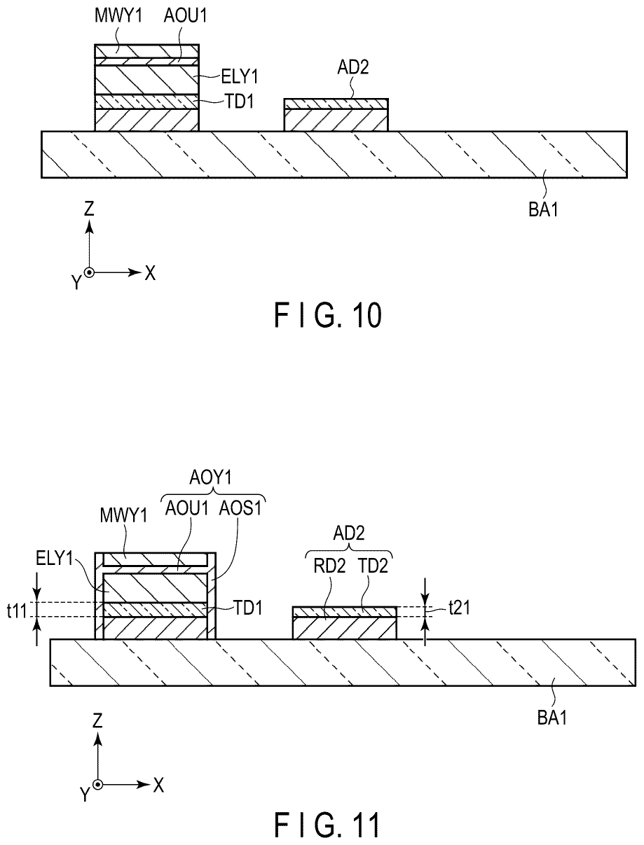

Using the island-shaped sacrificial layer MWY1 as a mask, the sacrificial layer AOM1 and the organic EL layer ELM1 are partially removed by etching. With this processing, the organic EL layer ELY1 and the upper layer of the sacrificial layer AOU1 are formed into an island-like shape between the anode AD1 and the sacrificial layer MWY1 (see FIG. 10). The sacrificial layer AOM1 and the organic EL layer ELM1 on the anode AD2 are removed.

A side wall AOS1 is formed in contact with side surfaces of the anode AD1, the organic EL layer ELY1, the upper layer AOU1, and the sacrificial layer MWY1. The side wall AOS1 is formed from the same material as that of the sacrificial layer AOM1. The upper layer AOU1 and the side wall AOS1 are collectively referred to as the sacrificial layer AOY1 (see FIG. 11).

In order to form the side wall AOS1, first, a material film that give rise to the side wall AOS1 is formed to as to covering the stacked body of the organic EL layer ELY1, the upper layer AOU1, and the sacrificial layer MWY1. After that, the material film is subjected to anisotropic etching, and thus only the area that is in contact with the side surface of the stacked body is left and the other areas are removed.

During the anisotropic etching, there is a risk that the transparent electrode TD2 of the anode AD2 may as well etched. Both the material film that give rise to the side wall AOS1 and the transparent electrode TD2 are formed from a material containing a metal oxide. When etching such metal oxides, it may be necessary in some cases to use an etching gas whose selectivity ratio is not taken. When an etching gas whose selectivity ratio is not taken is used, there is a risk that the transparent electrode TD2 may be etched, the transparent electrode TD2 may disappear, or the thickness of the transparent electrode TD2 may become thin as described above.

The thickness of the transparent electrode TD1 in FIG. 11 is defined as t11, and the thickness of the transparent electrode TD2 is defined as t21. By setting the thickness t20 in FIG. 6 to a sufficient level, even if the transparent electrode TD2 is etched by anisotropic etching in the processing step shown in FIG. 11, the transparent electrode TD2 does not disappear. The thickness of the transparent electrode TD2 decreases from the thickness t20 to the thickness t21 (t20>t21).

The thickness t11 of the transparent electrode TD1 is greater than the thickness t21 of the transparent electrode TD2 (t11>t21). On the transparent electrode TD1, a stacked body of the organic EL layer ELY1, the upper layer AOU1 of the sacrificial layer AOY1, and the sacrificial layer MWY1 is provided, and therefore the transparent electrode TD1 is not etched by anisotropic etching. That is, the thickness t11 indicated in FIG. 11 is similar to the thickness t10 indicated in FIG. 6 (t11=t10).

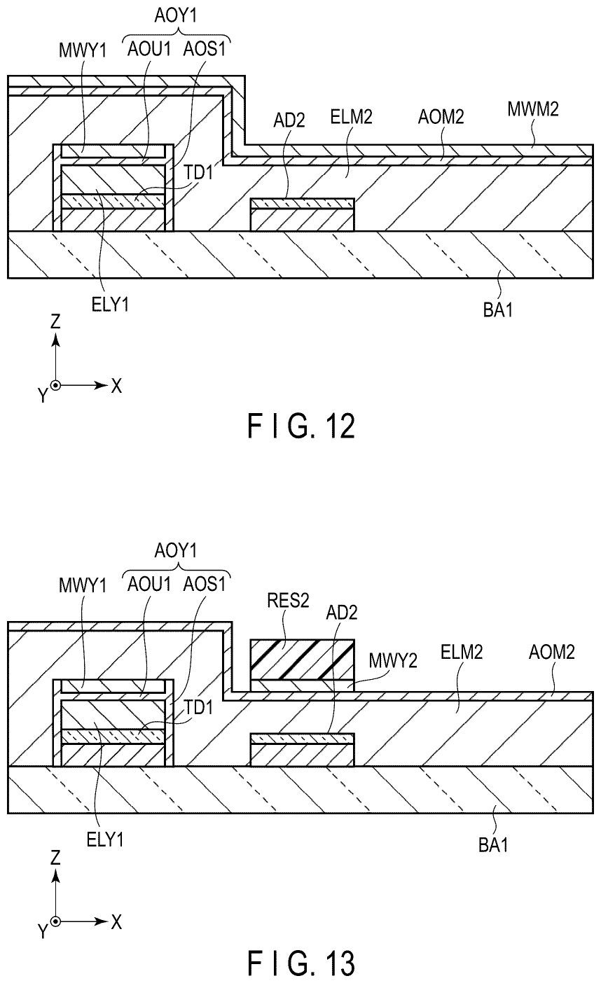

Thus, the organic EL layer ELM2, the sacrificial layer AOM2, and the sacrificial layer MWM2 are formed so as to cover the base BAL, the sacrificial layer AOY1, the sacrificial layer MWM1, and the anode AD2 (see FIG. 12). The organic EL layer ELM2 is an organic EL layer corresponding to the pixel PX2.

A resist mask RES2 is formed on the sacrificial layer MWM2 so as to oppose the anode AD2. Using the resist mask RES2, the sacrificial layer MWM2 is partially removed by etching. With this processing, a sacrificial layer MWY2 is formed into an island shape so as to oppose the anode AD2 and interpose the sacrificial layer AOM2 therebetween (see FIG. 13).

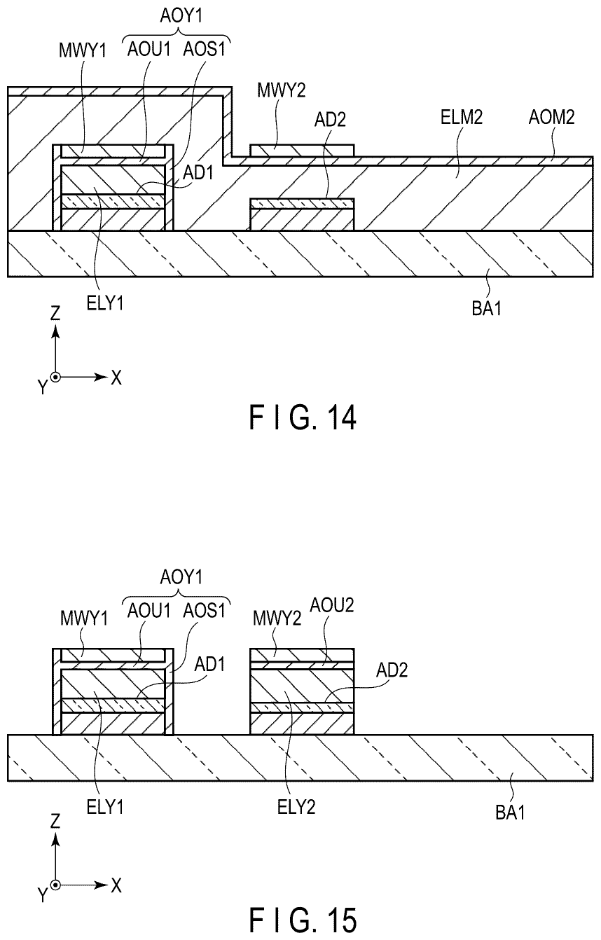

Next, the resist mask RES2 on the sacrificial layer MWY2 is removed (see FIG. 14).

Using the island-shaped sacrificial layer MWY2 as a mask, the sacrificial layer AOM2 and the organic EL layer ELM2 are partially removed by etching. With this processing, the organic EL layer ELY2 and the upper layer AOU2 of the sacrificial layer are formed into an island shape between the cathode CD2 and the sacrificial layer MWY2 (see FIG. 15).

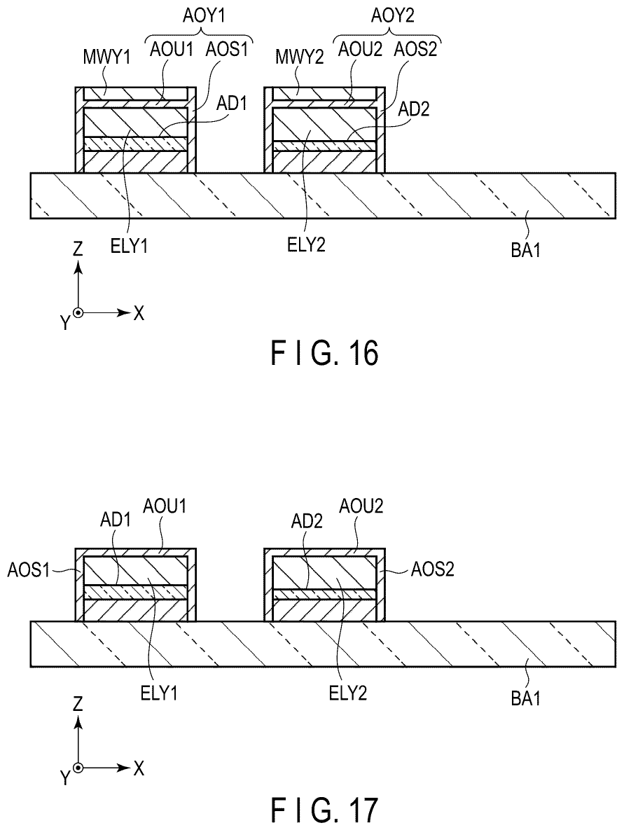

A side wall AOS2 is formed in contact with side surfaces of the anode AD2, the organic EL layer ELY2, the upper layer AOU2, and the sacrificial layer MWY2. The side wall AOS2 is formed of the same material as that of the sacrificial layer AOM2. The upper layer AOU2 and the side wall AOS2 are collectively referred to as the sacrificial layer AOY2 (see FIG. 16).

The sacrificial layer MWY1 and the sacrificial layer MWY2 are removed (see FIG. 17). At this time, the upper layer AOU1 of the sacrificial layer AOY1 and the upper layer AOU2 of the sacrificial layer AOY2 are planarized.

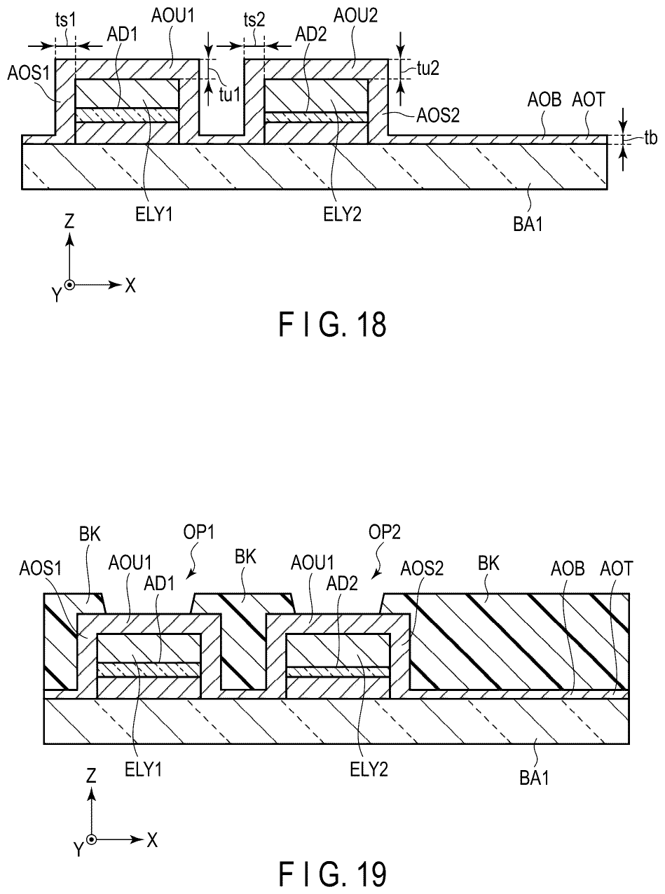

A sacrificial layer is formed so as to cover the upper layer AOU1 and the side wall AOS1 of the sacrificial layer AOY1 as well as the upper layer AOU2 and the side wall AOS2 of the sacrificial layer AOY2 from the same material as those of these sacrificial layers, that is, the same material as those of the sacrificial layer AOM1 and the sacrificial layer AOM2. With this configuration, the upper layer AOU1, the side wall AOS1, the upper layer AOU2, the side wall AOS2, and the newly formed sacrificial layers are integrated to form a sacrificial layer AOT (see FIG. 18).

The thickness tu1 of the upper layer AOU1 and the thickness tu2 of the upper layer AOU2 are approximately the same as the thickness ts1 of the side wall AOS1 and the thickness ts2 of the side wall AOS2, respectively. The area of the sacrificial layer AOT, which is in contact with the base BAL is referred to as an area AOB. The thickness tb of the region AOB is less than the thickness ts1, the thickness ts2, the thickness tu1, and the thickness tu2.

The bank BK is formed between the organic EL layer ELY1 and the organic EL layer ELY2, so as to be in contact with the sacrificial layer AOT. No bank BK is formed above the organic EL layer ELY1 and the organic EL layer ELY2. In other words, the aperture OP1 and the aperture OP2 are provided above the organic EL layer ELY1 and the organic EL layer ELY2, respectively (see FIG. 19).

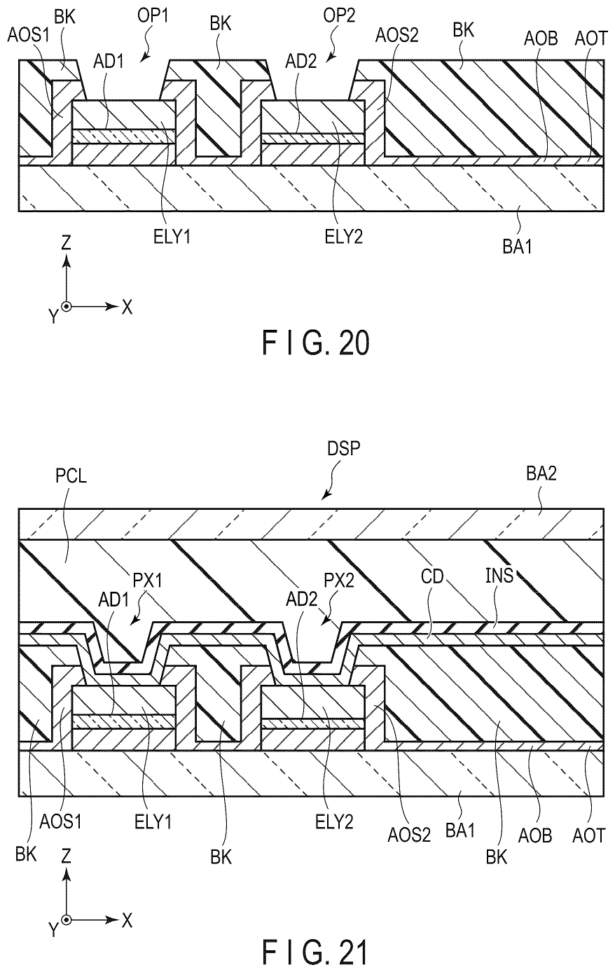

The sacrificial layer AOT in the aperture OP1 and the aperture OP2 is removed. With this processing, the organic EL layer ELY1 and the organic EL layer ELY2 are exposed in the aperture OP1 and the aperture OP2, which are provided in the bank BK and the sacrificial layer AOT (see FIG. 20).

The cathode CD, the insulating layer INS, and the insulating layer PCL are formed to cover the exposed organic EL layer ELY1 and organic EL layer ELY2, and the bank BK. The base BA2 is provided on the insulating layer PCL.

In the aperture OP1 and the aperture OP2, the cathode CD is provided on the organic EL layer ELY1 and the organic EL layer ELY2, respectively. Thus, as described above, the display device DSP of Embodiment 1 is formed (see FIG. 21).

The insulating layer INS is formed, for example, of silicon nitride (SiN). The insulating layer INS prevents moisture from entering the organic EL layer from the outside. The insulating layer PCL is formed, for example, from a resin insulating material. The insulating layer PCL has a function of planarizing the surface. For the base BA2, a material similar to that of the base BAL can be used.

In order to form the anode and the organic EL layer of the pixel PX3, which is the third pixel, the organic EL layer and two sacrificial layers should only be formed to cover the anode of the pixel PX3 as in the case of FIG. 12 after the process shown in FIG. 16 is completed. As in the case of the process of FIG. 16, after the side wall of the sacrificial layer of the pixel PX3 is formed, the process can proceed to that shown in FIG. 17.

In this embodiment, the pixel PX1, the pixel PX2, and the pixel PX3 can be a pixel PXR, a pixel PXG, and a pixel PXB, respectively. With this configuration, the thickness of the transparent electrode TD becomes thinner in the order of the pixel PXR, pixel PXG, and pixel PXB.

The sacrificial layer AOT (the sacrificial layer AOY1, the sacrificial layer AOY2, the side wall AOS1, the side wall AOS2, and the area AOB) corresponds to the protective layer AOL shown in FIG. 4. The protective layer AOL (the sacrificial layer AOT) formed of aluminum oxide covers the side surface of the organic EL layer, thereby making it possible to protect the organic EL layer.

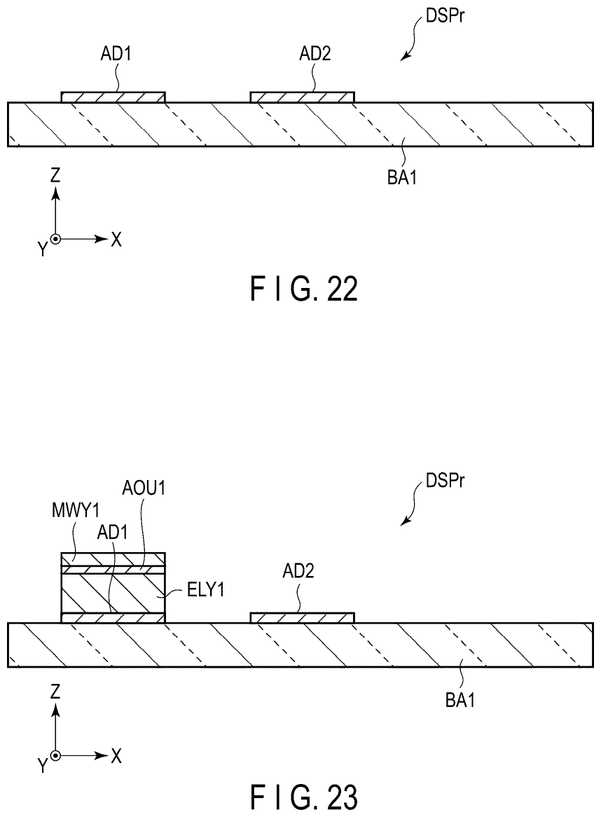

FIGS. 22 to 24 are each a cross-sectional diagram showing a respective step in a method of manufacturing a display device of a comparative example. In the manufacture of a display device DSPr of the comparative example, first, an anode AD1 and an anode AD2 are formed on the base BAL (see FIG. 22). It is assumed here that the anode AD1 and the anode AD2 in the comparative example are transparent electrodes formed of a metal oxide. Example of such a metal oxide include indium tin oxide and indium zinc oxide mentioned above. The process shown in FIG. 22 corresponds to the process shown in FIG. 6.

Through the processing steps shown in FIGS. 7 to 9, the organic EL layer ELY1, the upper layer of the sacrificial layer AOU1, and the sacrificial layer MWY1 are formed on the anode AD1. On the anode AD2, the sacrificial layer has been removed (see FIG. 23). The process shown in FIG. 23 corresponds to the process shown in FIG. 10.

Next, as in FIG. 11, a side wall AOS1 is formed so as to be in contact with side surfaces of the anode AD1, the organic EL layer ELY1, the upper layer AOU1, and the sacrificial layer MWY1. As in the case described above, a material film, which gives rise to the side wall AOS1, is formed to cover the stacked body of the organic EL layer ELY1, the upper layer AOU1, and the sacrificial layer MWY1. Then, the material film is subjected to anisotropic etching so as to leave only the area that contacts the side surface of the stacked layer and remove the other areas, thus forming the side wall AOS1.

The material of the side wall AOS1 is the same as that of the sacrificial layer AOM1, that is, for example, aluminum oxide (Alox). On the other hand, the anode AD1 and the anode AD2 are formed of a metal oxide, for example, as described above.

That is, the side wall AOS1, as well as the anode AD1 and the anode AD2, are formed from a material containing a metal oxide. Here, when etching such a metal oxide, it may be necessary in some cases to use an etching gas whose selectivity ratio cannot be taken.

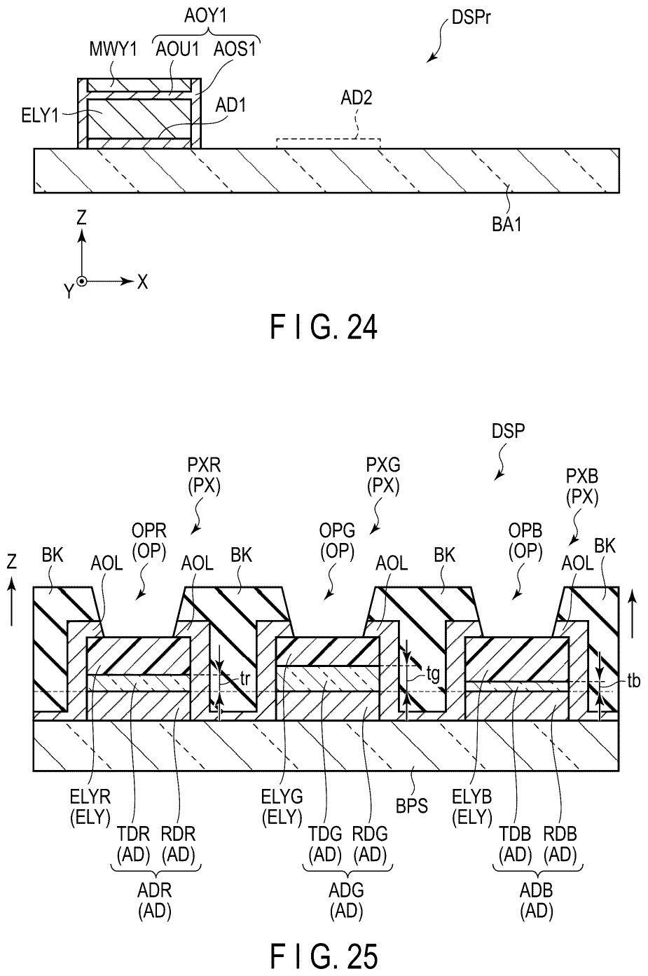

In this case, there is a risk that the anode AD2 may be removed together as well by the etching carried out to form the side wall AOS1 (see FIG. 24). If the anode is removed, the desired characteristics cannot be obtained for that pixel due to the high voltage. In this way, the display quality will be reduced in such a display device.

In the display device DSP of this embodiment, the anode AD is formed from a reflective electrode RD and a transparent electrode TD. The transparent electrode TD is formed as a film in the initial film formation process so as to have such a thickness that will not disappear even if etched. In this embodiment, the thickness t10 and the thickness t20 shown in FIG. 6 are set to be sufficient thicknesses. That is, the thickness t10 and the thickness t20 are each at a sufficient level so that the transparent electrode TD does not disappear due to etching in the subsequent processing steps. The thickness of the transparent electrode TD becomes less in the order of the pixel PXR that emits red light, the pixel PXG that emits green light, and the pixel PXB that emits blue light.

In the manufacturing process shown in FIGS. 6 to 21, the display device DSP of this embodiment can be manufactured without eliminating the anodes. Thus, it is possible to prevent the display quality of the display device DSP from deteriorating while avoiding the pixels from not emitting light.

### Embodiment 2

FIG. 25 is a cross-sectional diagram showing a configuration example of a display device in Embodiment 2. The configuration example shown in FIG. 25 is different as compared to the configuration example shown in FIG. 4 in that the thickness of the transparent electrode TDG of the green-emitting pixel PXG is greater than that of the transparent electrode TDR of the red-emitting pixel PXR.

In FIG. 25, the thickness tg of the transparent electrode TDG is greater than the thickness tr of the transparent electrode TDR. The thickness tr of the transparent electrode TDR is greater than the thickness tb of the transparent electrode TDB, (tg>tr>tb). The thicknesses of the reflective electrode RDR, reflective electrode RDG, and reflective electrode RDB are the same as each other as in the case of FIG. 4.

The green light emitted from the organic EL layer ELYG of the pixel PXG has a higher luminance than that of red or blue light. Therefore, even if the light is absorbed by the transparent electrode TDG to decrease the light amount, the luminance of the pixel PXG does not decrease extremely as compared to the luminance of the pixel PXR or the luminance of the pixel PXB.

In order to obtain a display device DSP shown in FIG. 25, the manufacturing processing steps shown in FIGS. 6 to 21 can be adopted as in the case of Embodiment 1. In this case, the pixel PX1 and the pixel PX2 are respectively referred to as the pixel PXG and the pixel PXR. The transparent electrode TD1 and the transparent electrode TD2 correspond to the transparent electrode TDG and the transparent electrode TDR, respectively. In the manufacturing process shown in FIG. 6, the thickness t10 of the transparent electrode TD1 (transparent electrode TDG) is set greater than the thickness t20 of the transparent electrode TD2 (transparent electrode TDR) (t10>t20).

In the processing step shown in FIG. 11 as well, the thickness t11 of the transparent electrode TD1 (transparent electrode TDR) is greater than the thickness t21 of the transparent electrode TD2 (transparent electrode TDR) (t11>t21).

The pixel PXB corresponds to the pixel PX3 described in Embodiment 1. The transparent electrode of the pixel PX3 is referred to as a transparent electrode TD3. The initial thickness of the transparent electrode TD3, that is, the thickness of the transparent electrode TD3 formed in the process shown in FIG. 6, is referred to as a thickness t30. In addition, the thickness of the transparent electrode TD3 after anisotropic etching, that is, the thickness of the transparent electrode TD3 in the processing step corresponding to that of FIG. 11, is set to a thickness t31.

The thickness t30 is less than the thickness t10 and the thickness t20. In other words, an establishment of t10>t20>t30 is established. Further, the thickness t31 is less than the thickness t11 and the thickness t20. In other words, a relationship of t11>t21>t31 is established. That is, the thickness of the transparent electrode TD3 of pixel PX3, that is, the thickness of the transparent electrode TDB of the pixel PXB is less than the thickness of the transparent electrode of the pixel PXR or the pixel PXG in its initial stage or after the anisotropic etching.

As described above, it is also possible in Embodiment 2 to manufacture the display device DSP without eliminating the transparent electrode of the anode. In this manner, it is possible to prevent the display quality of the display device DSP from deteriorating while avoiding the pixels from not emitting light.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels including first pixels that emit red light, second pixels that emit green light, and third pixels that emit blue light; and
a bank provided between each adjacent pair of the plurality of pixels, wherein
each of the plurality of pixels comprises, on a base,
an anode including a reflective electrode and a transparent electrode,
an organic EL layer provided on the anode, a protective layer provided to cover a side surface of the organic EL layer, and
a cathode disposed in an aperture of the protective layer and the bank, so as to be in contact with the organic EL layer,
the first pixel comprises a first anode including a first reflective electrode and a first transparent electrode,
the second pixel comprises a second anode including a second reflective electrode and a second transparent electrode,
the third pixel comprises a third anode including a third reflective electrode and a third transparent electrode, and
a first thickness of the first transparent electrode, a second thickness of the second transparent electrode, and a third thickness of the third transparent electrode are less in this order.

2. The display device according to claim 1, wherein
the first transparent electrode and the second transparent electrode contain indium tin oxide or indium zinc oxide.

3. The display device according to claim 1, wherein
the protective layer is formed of aluminum oxide.

4. The display device according to claim 1, wherein
the reflective electrode contains silver or a molybdenum-tungsten alloy.
